(19) United States
(12) Patent Application Publication
(10) Pub. No.: US 2008/0135936 A1
(43) Pub. Date: Jun. 12, 2008

(54) SEMICONDUCTOR DEVICE AND MANUFACTURING METHOD THEREOF

(76) Inventor: Kazuaki NAKAJIMA, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/948,292

(22) Filed: Nov. 30, 2007

(30) Foreign Application Priority Data
Dec. 8, 2006 (JP) 2006-332396

(51) Int. Cl. H01L 29/94; H01L 21/3205

(52) U.S. Cl. 257/347; 438/585; 257/E21.294; 257/E29.345

(57) ABSTRACT

The method of manufacturing a semiconductor device includes: forming a gate insulating film on a semiconductor substrate; forming a thin silicon layer on the gate insulating film; and forming a metal film on the thin silicon layer, having a work function at the interface with respect to the gate insulating film of a value within a predetermined range.

### CROSS REFERENCE TO RELATED APPLICATION

This application is based upon and claims the benefit of priority from the prior Japanese Patent Application No. 2006-332396 filed on Dec. 8, 2006; the entire contents of which are incorporated herein by reference.

### BACKGROUND OF THE INVENTION

1. Field of the Invention

The present invention relates to a method of manufacturing a semiconductor device such as an MIS capacitor or an MIS transistor, which uses an electrically conductive film as the gate electrode thereof.

2. Description of the Related Art

Conventionally, in order to achieve a high performance and highly integrated MOS capacitor or MOSFET as an MIS capacitor or an MIS transistor, miniaturization of these devices have been researched. However, in a semiconductor device (hereinafter referred to as a device) after the design rule generation of 0.1 μm line width (hereinafter referred to as a 0.1 μm generation), it is said that there is a limit for scaling of a gate oxide film acting as the gate insulating film. This is due to that as the thickness of the gate oxide film becomes thinner, the gate leakage current due to tunnel current increases significantly. Further, when polycrystal silicon is used as the gate electrode, a depletion layer is formed on the interface with respect to the gate insulating film, and since the depletion cannot be ignored in the 0.1 μm generation, thinning of the equivalent oxide thickness cannot be achieved as desired.

As an approach to avoid the problems, increasing the dielectric constant of the gate insulating film and use of a metal gate electrode are investigated; the reason of the former is to increase physical film thickness and suppress tunnel current by replacing the gate insulating film into a high dielectric material film, and the reason for the latter is to prevent depletion of the gate electrode by metalizing the gate electrode. In recent years, especially, materials for a high dielectric material gate insulating film have been energetically developed, and new materials such as ZrO₂ and HfO₂ are discussed in academic conferences, resulting in competition in thinning of the equivalent oxide thickness. However, time is required until discussion including reliability such as discussion for the known silicon dioxide film can be performed.

On the other hand, as compared to the development of the high dielectric material film, investigation of the metal gate electrode seems to be lacked of enthusiasm. However, as indicated by ITRS 2003, it is considered that, in a region where the physical thickness of the gate insulating film is smaller than 1.0 nm, it is difficult to achieve a transistor by using a known polycrystal silicon electrode. The reason of this is in that the depletion layer formed in the gate electrode is as large as 0.3 to 0.5 nm, and occupies a large ratio with respect to the equivalent oxide thickness (an order of 1.5 nm) of the current gate insulating film, and as the results, the capacitance accompanied with the depletion is serially connected to the capacitance originating from the insulating layer, leading to decrease of the capacitance. Therefore, development of the metal gate electrode is also necessary for lengthening the life of a silicon-based oxide film to the 0.1 μm generation.

However, a new problem occurs, which is different from the problems of known structure through a polycrystal silicon film (including polycide structure, salicide structure, and poly metal structure). For the known gate electrode structure through a polycrystal silicon film, the threshold value of a transistor is determined by the concentration of impurities in the channel region, and the concentration of impurities in the polycrystal silicon film. However, for the metal gate electrode structure, the threshold value of the transistor is determined by the concentration of impurities in the channel region and the work function of the gate electrode.

For the known gate electrode using polycrystal silicon, the work functions of a pMOS electrode material and an nMOS electrode material can be set to 5.0 eV corresponding to the maximum value of the electron energy of the valence band of the polycrystal silicon, and to 4.1 eV corresponding to the minimum value of the electron energy of the conduction band thereof, respectively.

Therefore, when the metal gate electrode is used, it is also preferable to use a metal or the compound thereof, having a work function of 5.0 eV, as the pMOS electrode material.

Among metals, a tungsten electrode (referred to as a W electrode) having a work function of 5.0 eV, is a promising metal as the pMOS electrode material. Although a W film process by means of a chemical vapor deposition (CVD) method using a W(CO)₆ gas for the source gas is included as one candidate of approaches configured to form the W electrode, it is known that many carbons (C) are included in the W film, and the residual C are precipitated in the vicinity of the interface with respect to the gate insulating film by means of a post-thermal process, resulting in a cause of fixed charges.

Incidentally, as a known technology, as described in, for example, Japanese Patent Laid-Open No. 2005-093856, a method of manufacturing a semiconductor device is disclosed, which includes forming a gate insulating film on a semiconductor substrate by means of a film formation process, and subsequently forming a gate electrode including an electrically conductive material having a different work function.

### SUMMARY OF THE INVENTION

According to one embodiment of the present invention, a method of manufacturing a semiconductor device is provided, which includes: forming a gate insulating film on a semiconductor substrate; forming a silicon layer on the gate insulating film; and forming a metal film on the silicon layer, having a work function at the interface with respect to the gate insulating film of a value within a predetermined range.

According to another embodiment of the present invention, a semiconductor device including a semiconductor substrate, a gate insulating film disposed on the semiconductor substrate, a metal film disposed on the gate insulating film, so as to have a work function at on interface with respect to the gate insulating film of a value within a predetermined range, and a metal-silicon-carbon compound disposed between the gate insulating film and the metal film, which binds to the carbon component contained in the metal film and has a predetermined film thickness preventing carbon components from being precipitated into the gate insulating film from the metal film, is provided.

### BRIEF DESCRIPTION OF THE DRAWINGS

FIG. 1A is a cross-sectional view illustrating a part of a main process of the method configured to manufacture a semiconductor device according to a first embodiment of the present invention;

FIG. 1B is a cross-sectional view illustrating a part of another main process of the method configured to manufacture the semiconductor device according to the first embodiment of the present invention;

FIG. 2A is a cross-sectional view illustrating a part of a main process of the method configured to manufacture a prior art semiconductor device;

FIG. 2B is a cross-sectional view illustrating a part of another main process of the method configured to manufacture the prior art semiconductor device;

FIG. 3 is a characteristic view illustrating the gate bias fluctuation characteristics of a semiconductor device when low current stress is applied;

FIG. 4 is a characteristic view illustrating the gate bias fluctuation amount ΔVg and the fluctuation of the work function φm of a semiconductor device with respect to the thickness of Si layer;

FIG. 5A is a cross-sectional view illustrating a part of a main process of the method configured to manufacture a semiconductor device according to a second embodiment of the present invention;

FIG. 5B is a cross-sectional view illustrating a part of another main process of the method configured to manufacture the semiconductor device according to the second embodiment of the present invention;

FIG. 5C is a cross-sectional view illustrating a part of another main process of the method configured to manufacture the semiconductor device according to the second embodiment of the present invention;

FIG. 5D is a cross-sectional view illustrating a part of another main process of the method configured to manufacture the semiconductor device according to the second embodiment of the present invention;

FIG. 5E is a cross-sectional view illustrating a part of another main process of the method configured to manufacture the semiconductor device according to the second embodiment of the present invention;

FIG. 6A is a cross-sectional view illustrating a part of a manufacturing process following to the process in FIG. 5E;

FIG. 6B is a cross-sectional view illustrating a part of another manufacturing process following to the process in FIG. 5E;

FIG. 6C is a cross-sectional view illustrating a part of another manufacturing process following to the process in FIG. 5E;

FIG. 6D is a cross-sectional view illustrating a part of another manufacturing process following to the process in FIG. 5E;

FIG. 7A is a cross-sectional view illustrating a part of a process of the method configured to manufacture a semiconductor device according to a third embodiment of the present invention;

FIG. 7B is a cross-sectional view illustrating a part of another process of the method configured to manufacture the semiconductor device according to the third embodiment of the present invention;

FIG. 7C is a cross-sectional view illustrating a part of another process of the method configured to manufacture the semiconductor device according to the third embodiment of the present invention;

FIG. 7D is a cross-sectional view illustrating a part of another process of the method configured to manufacture the semiconductor device according to the third embodiment of the present invention;

FIG. 7E is a cross-sectional view illustrating a part of another process of the method configured to manufacture the semiconductor device according to the third embodiment of the present invention;

FIG. 8A is a cross-sectional view illustrating a part of a manufacturing process following to the process in FIG. 7E;

FIG. 8B is a cross-sectional view illustrating a part of another manufacturing process following to the process in FIG. 7E; and

FIG. 8C is a cross-sectional view illustrating a part of another manufacturing process following to the process in FIG. 7E.

### DETAILED DESCRIPTION OF THE PREFERRED EMBODIMENTS

Embodiments of the present invention will be described with reference to drawings.

### First Embodiment

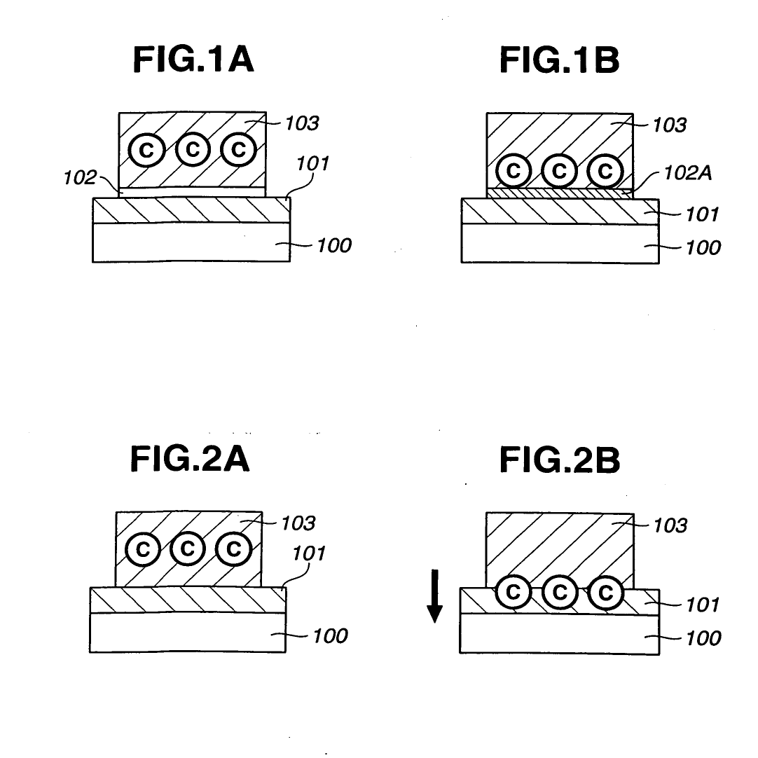

FIGS. 1A and 1B, respectively, illustrates a cross-sectional view of a part of a main process of the method configured to manufacture a semiconductor device according to a first embodiment of the present invention, and FIGS. 2A and 2B, respectively, illustrates a cross-sectional view of a part of a main process of the method configured to manufacture a semiconductor device of a prior art. Here, the manufacturing process configured to form an MOS capacitor as an MIS capacitor being a semiconductor device, will be described.

First, the manufacturing method of an MOS capacitor of a prior art, is described, with reference to FIGS. 2A and 2B.

As illustrated in FIG. 2A, as a gate insulating film, a silicon dioxide film (SiO₂) 101 is formed on a single-crystal-silicon substrate 100 acting as a semiconductor substrate, a tungsten film (hereinafter referred to as a W film) 103 (film thickness: 50 nm) is deposited on the silicon dioxide film by means of a CVD method, using, for example, an organic source, and the W film 103 is subjected to anisotropic etching into a desired pattern, resulting in formation of a gate electrode. After that, as illustrated in FIG. 2B, the gate electrode is subjected to a heating treatment at a temperature of 450° C. in a 10% diluted hydrogen atmosphere.

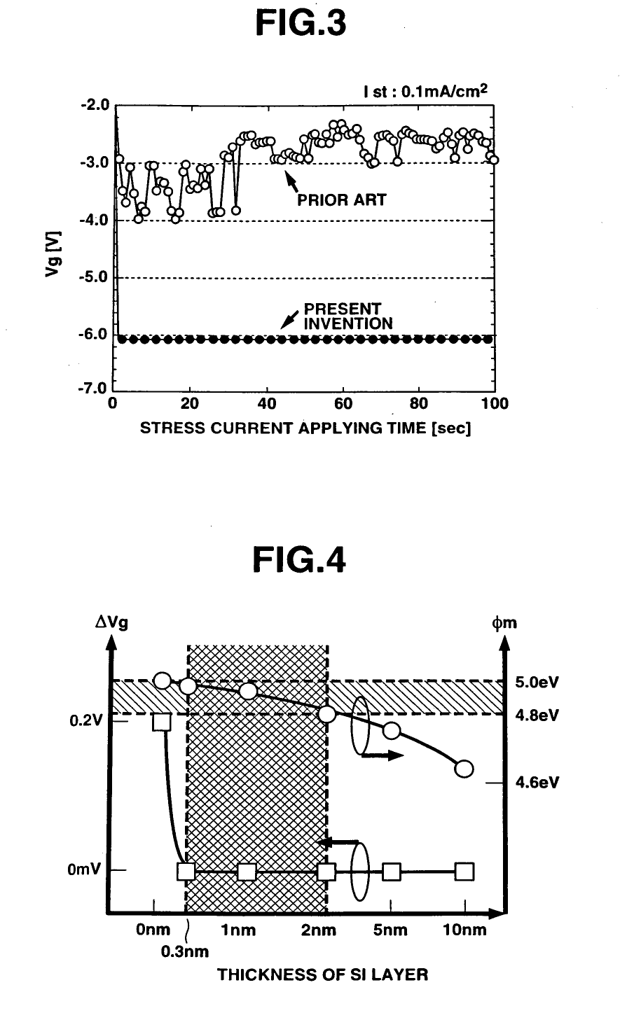

In FIG. 3, gate bias fluctuation characteristics (ΔVg-t characteristics) of an MOS capacitor of a prior art, manufactured in this manner, when low current stress is applied to the MOS capacitor, is illustrated. The gate bias fluctuation characteristics is the measured results of the change in the gate bias voltage Vg between a gate electrode and a reference potential point (earth plane) when a current source is connected between the gate electrode of a silicon substrate and the reference potential point at the opposite side of the silicon substrate, and constant stress current (0.1 mA/cm²) is flowed from the gate electrode to the reference potential point of the silicon substrate. At that time, it is known that the gate bias voltage Vg, when low current stress is applied, changes largely with respect to a time axis within a range of −2 V to −4 V. The range is a fluctuation amount (ΔVg). This is because of the fact that C elements contained in the W film 103 diffuse into the gate insulating film in a heat treatment process of a latter stage (hereinafter referred to as a post-thermal process), and the diffused C elements form trapping levels in the insulating film. As the results of investigation of the depth direction distribution of component elements by means of a secondary ion mass spectrometer (SIMS), it was known that C elements are spread from the W electrode to the gate insulating film. Since the W film is formed by means of a CVD method using an organic source, C will remain in the film to an order of several %. In other words, it is considered that the residual C elements diffuse into the oxide film by means of a heat treatment, and the diffused C elements act as trapping levels, resulting in the cause of the gate bias fluctuation characteristics, as mentioned-above.

Therefore, the manufacturing process of an MOS capacitor according to a first embodiment of the present invention, will be described, with reference to FIGS. 1A and 1B.

As illustrated in FIG. 1A, as the gate insulating film, a silicon dioxide film (SiO₂) 101 is formed on a single-crystal-silicon substrate 100 acting as a semiconductor substrate, and before a W film is formed, a thin silicon layer (hereinafter referred to as a Si layer) 102 as thin as 1 nm is formed at conditions, for example, SiH₄ gas: 300 sccm, pressure: 5 Torr, and time: 10 seconds. After that, similarly to the prior art, a W film 103 (thickness: 50 nm) is deposited by means of a CVD method using an organic source, and a tungsten film (hereinafter referred to as a W film) 103 is subjected to anisotropic etching into a desired pattern, resulting in formation of a gate electrode. After that, as illustrated in FIG. 1B, the gate electrode is subjected to a heating treatment at a temperature of 450° C. in a 10% diluted hydrogen atmosphere. By means of such a heating treatment, the thin Si layer 102 is bound to C in the W film 103 and is further bound to W, resulting in formation of a WSiC film 102A being a metal-silicon-carbon compound.

As a result, as illustrated in the gate bias fluctuation characteristics when low current stress is applied in FIG. 3, according to the present invention, few of the gate bias fluctuation characteristics of an MOS capacitor (ΔVg) is observed as compared to that of the prior art. The reason of this is in that the Si layer (in other words, the WSiC layer) prevents the above-mentioned carbons (C) from diffusing in the gate oxide film. The binding strength of C and Si is very strong, thereby, once a Si—C bond is formed, the bond hardly thermally decomposes. Therefore, not only when the W film is formed, but also in the post-thermal process after the W film is formed, the Si—C bonded layer at the interface between the W electrode and the gate insulating film is stable and the diffusion of C into the gate insulating film is suppressed.

Thus, how the gate bias fluctuation amount (ΔVg) of an MOS capacitor depends on the thickness of the Si layer, is investigated, next. In FIG. 4, the measured results of the gate bias fluctuation amount (ΔVg) of an MOS capacitor with respect to thickness of the Si layer are illustrated, and simultaneously, the fluctuation of the work function (φm) thereof with respect to the thickness of the Si layer is also illustrated. As a result, it is understood that as the thickness of the interface layer between the gate electrode and the gate insulating film increases, the ΔVg decreases. The results in FIG. 4 indicate that, in order to suppress the diffusion of C, it is sufficient for the thickness of the Si layer to be equal to or greater than 0.3 nm.

However, it is not good merely thickening the thickness of the Si layer further. In a metal gate electrode, the work function itself of a material becomes important. Here application of the W electrode as an electrode material for a pMOS is intended, thereby, it is required for the pMOS electrode to have a work function being at least equal to or greater than 4.8 eV near the maximum value of 5.0 eV of the electron energy of the valence band of polysilicon. However, increasing the thickness of the Si layer means that the work function of the pMOS electrode has a value nearer to the value of the work function of the Si layer, specifically, a value near 4.6 eV. Thereby, as the result of calculation of work functions with respect to the thicknesses of the interfacial layer, it is known that as the thickness of the Si layer increases the work function tends to decrease, and when the thickness has a value greater than 2 nm, the work function has a value being smaller than 4.8 eV.

Therefore, in order to suppress the gate bias fluctuation amount and to obtain a desired work function, it is desirable for the thickness of the Si interfacial layer to be within a range of 0.3 nm to 2 nm.

According to the first embodiment, when a metal electrode is formed on the gate insulating film as the pMOS electrode material, the carbon components are prevented from diffusing into the gate insulating film from inside the metal film, enabling the cause of fixed charges to be reduced.

### Second Embodiment

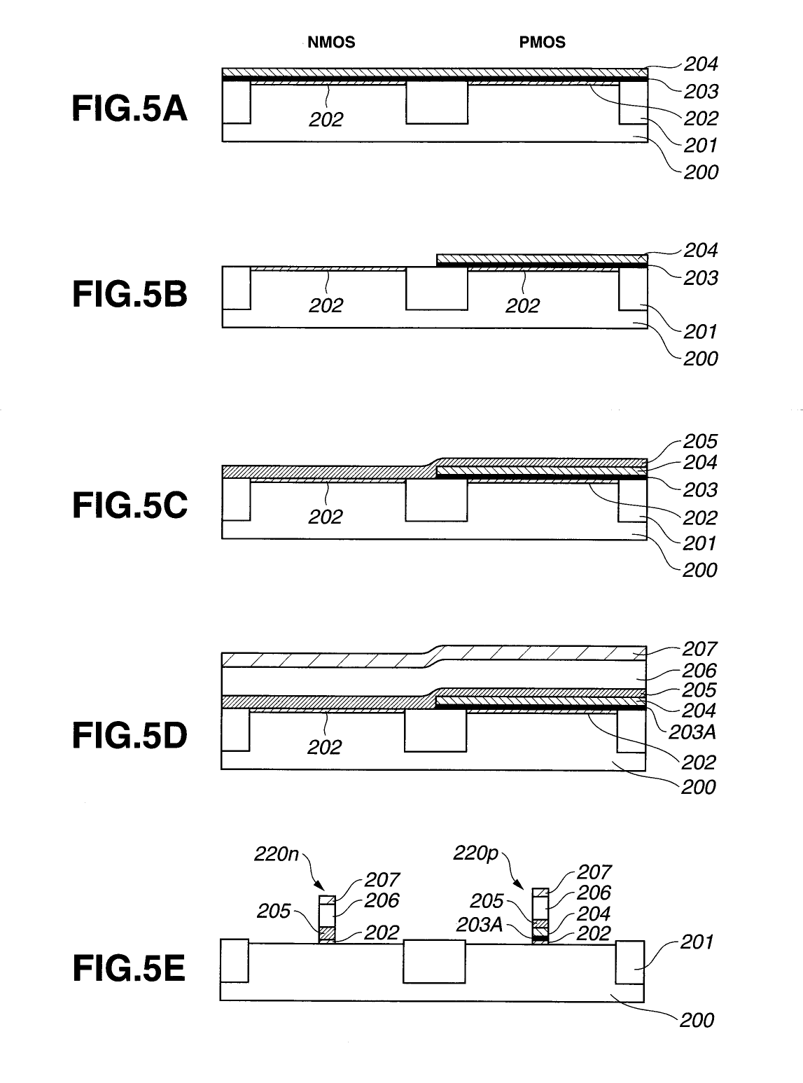

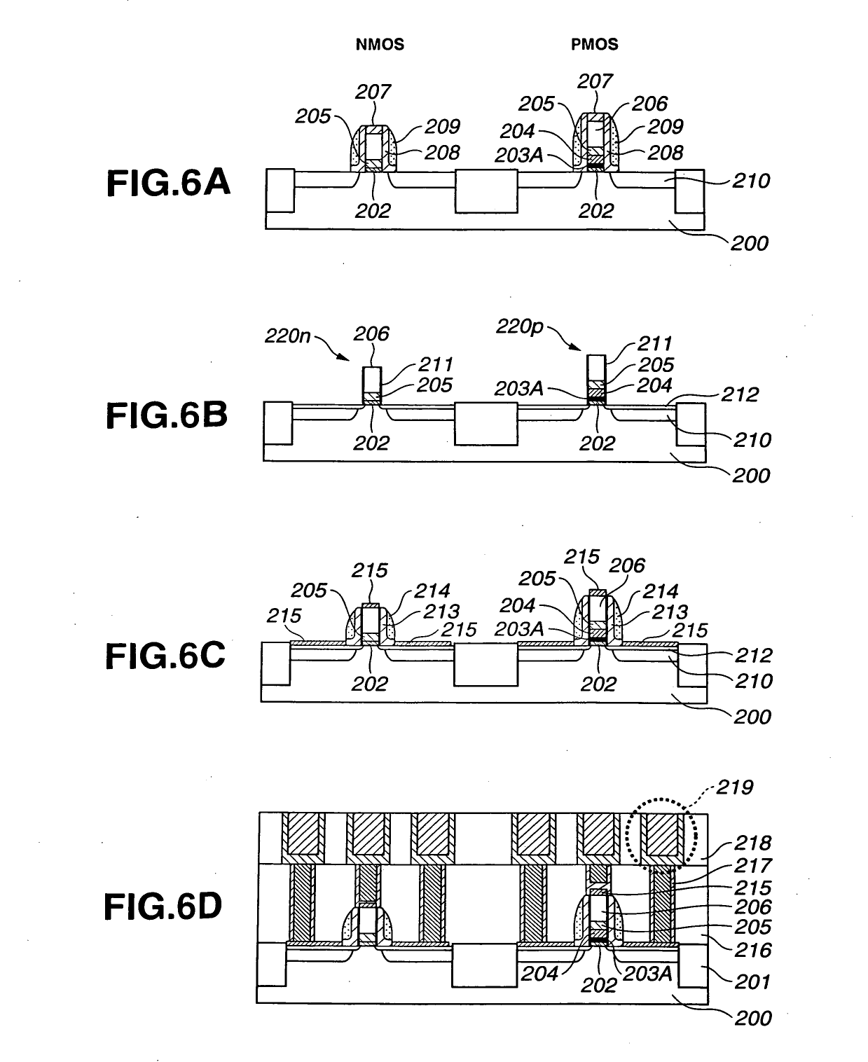

In FIGS. 5A, 5B, 5C, 5D, 5E, 6A, 6B, 6C, and 6D, cross-sectional views of a part of each process of the method configured to manufacture a semiconductor device according to a second embodiment of the present invention, are illustrated, and in FIGS. 6A, 6B, 6C, and 6D, cross-sectional views of a part of each process following to the process in FIG. 5E are illustrated. Here the manufacturing process configured to form an MOSFET as an MIS-transistor being a semiconductor device, will be described. In addition, as the manufacturing process of the MOSFET according to the present invention, a process configured to form a pMOSFET (hereinafter referred to as a pMOS) on the silicon substrate will be described, however, it will be described as a manufacturing process of a CMOS (Complementary MOS) integrated circuit, where an nMOSFET (hereinafter referred to as an nMOS) making a pair to the pMOS is simultaneously formed.

As illustrated in FIG. 5A, a gate insulating film 202 containing hafnium is formed on a single-crystal-silicon substrate 200 being a semiconductor substrate having element isolation 201, by means of, for example, a chemical vapor deposition (CVD) method using an organic source.

After that, before a W film is formed, a thin silicon layer (hereinafter referred to as a Si layer) 203 as thin as 0.5 nm is formed at conditions, for example, SiH₄ gas: 300 sccm, pressure: 5 Torr, and time: 10 seconds.

A W film 204 having a work function of 4.9 eV and a thickness of 10 nm, is formed on the thin silicon layer 203, by means of, for example, a CVD method using an organic source. This enables diffusion of C at a stage of formation of the W film and the gate bias fluctuation amount to be suppressed. In addition, a WSiC film 203A being a metal-silicon-carbon compound is formed, by the fact that the Si layer 103 is bound to C in the W film 204 and is further bound to W.

Next, as illustrated in FIG. 5B, for example, the W film 204 and the Si layer 203 in the NMOS region, are released.

Further, as illustrated in FIG. 5C, for example, a WSiN film 205 having a work function of 4.2 eV and a thickness of 10 nm, is formed by means of a CVD method.

As illustrated in FIG. 5D, after a polycrystalline silicon film 206 is deposited, an As⁺ ion is ion-implanted into the NMOS region of the polycrystalline silicon film 206, and a B⁺ ions is ion-implanted into the pMOS region thereof. The ion implantation is performed in order to cause the polycrystalline silicon film 206 to be close to a low electric resistance electrical conductor as much as possible. Further, a silicon nitride film 207 was deposited on the polycrystalline silicon film 206.

At that time, in the NMOS region, the gate insulating film 202 and the WSiN film 205 having a work function of 4.2 eV are brought into contact with each other, and in the pMOS region, the gate insulating film 202 and the W film 204 having a work function of 4.9 eV are brought into contact with each other. After that, when a transistor is formed, this causes the work function of a metal material contacting with the gate insulating films, to control the threshold value of the transistor. At that time, since the thickness of the Si layer 203 is as thin as 0.5 nm, the influence to the work function of the W film is small.

As illustrated in FIG. 5E, gate electrodes 220n and 220p are formed by subjecting the silicon nitride film 207, the polycrystalline silicon film 206, the WSiN film 205, and the W film 204 to anisotropic etching into a pattern having a gate width of, for example, 30 nm.

As illustrated in FIG. 6A, after being deposited on the side wall parts of the electrode pattern, a silicon dioxide film 208 and a silicon nitride film 209 is subjected to etching back, causing the side wall parts of the electrode pattern to have a structure surrounded by the silicon dioxide film 208 and the silicon nitride film 209, The side walls composed of the silicon dioxide film 208 and the silicon nitride film 209 are disposed so that a deep diffusion layers 210 to be formed after the next ion implantation are formed in the silicon substrate 200 at the both sides of the gate region, apart from each other by a suitable distance. Further, the deep diffusion layers 210 are formed, for example, by ion-implanting a P⁺ ion into the nMOS region and a B⁺ ion into the pMOS region, and subjecting the both regions to a heating treatment at 1030° C. for 5 seconds. The deep diffusion layers 210 have a function to form the drain region and the source region of an MOS transistor together with the below-mentioned shallow diffusion layers 212.

After that, as illustrated in FIG. 6B, the silicon dioxide film 208 and the silicon nitride film 209 which are the side wall parts of the electrode pattern, are released. At that time together with the side wall parts the silicon nitride films 207 are also released. Next, after being deposited on the side wall parts of the electrode pattern, silicon nitride films 211 are subjected to etching back, causing the side wall parts of the electrode pattern to have a structure surrounded by the silicon nitride films 211.

Further, the shallow diffusion layers 212 are formed, for example, by ion-implanting an As⁺ ion into the nMOS region and a B⁺ ion into the pMOS region, and subjecting the both regions to a heating treatment at 800° C. for 5 seconds.

In addition, when each of the deep diffusion layers and the shallow diffusion layers are formed, thermal processes (heating treatments) are necessarily required in order to activate impurities after they are ion-implanted. Since the deep diffusion layers are formed prior to the shallow diffusion layers in first, the deep diffusion layers are subjected to activation by means of a thermal process, twice, but the shallow diffusion layers are subjected to activation by means of a thermal process, only once. For the deep diffusion layers, since being apart from each other by a predetermined distance at the both side of the gate region, by formation of the side wall parts, the deep diffusion layers hardly affected by the diffusion in spite of being subjected to the thermal processes twice. For the shallow diffusion layers, since being subjected to the thermal process only once, the shallow diffusion layers have few increase of the diffusion range extending to the substrate plane direction due to the diffusion. In other words, forming the deep diffusion layers prior to the shallow diffusion layers in first, results in suppression of extension of the shallow diffusion layers in the substrate plane direction, enabling the gate length (the channel length) to be prevented from being too short (referred to as a short channel effect).

Subsequently, as illustrated in FIG. 6C, side walls composed of a silicon dioxide film 213 and a silicon nitride film 214 are formed again. The side walls composed of the silicon dioxide film 213 and the silicon nitride film 214 are disposed in order to form a silicide layer 215 to be formed after the next heating treatment on the silicon substrate 200 at the both sides of the gate region, with being apart from each other by a suitable distance. Then, after causing reaction of Ni and the silicon substrate to occur by depositing a Ni film (10 nm) on the entire surface of the silicon substrate, and subjecting them to a heating treatment at an order of 350° C. for 30 seconds, unreacted Ni films are removed by using, for example, a mixed-solution of sulfuric acid and oxygenated water. Then, the side walls are subjected to a heating treatment at an order of 500° C. for 30 seconds, and at that time, silicide layers 215 are formed on the gate electrode and on the diffusion layers, respectively. The silicide layer 215 has low electrical resistance and metallic contact with a contact 217 mentioned later. In addition, in the present embodiment, the silicide layers 215 is formed on the gate electrode so as to remain the polycrystalline silicon film 206, however, all of the polycrystalline silicon film of the gate electrode may be a silicide layer.

As illustrated in FIG. 6D, a desired contact pattern is formed on a first interlayer film 216, for example, a Ti/TiN/W film is buried inside the contact pattern, and the surface of the buried contact pattern is flattened by means of a CMP method, resulting in formation of the contact 217. Subsequently, a second interlayer film 218 is deposited on the contact 217, and a desired trench pattern is formed, subsequently a TaN/Cu film is buried inside the trench pattern, and the surface of the buried trench pattern is flattened by means of the CMP method, resulting in formation of a Cu wiring 219 electrically connecting between contacts 217.

The above-mentioned manufacturing process enables formation of a dual metal transistor which includes an nMOS electrode having a work function of 4.2 eV and a pMOS electrode having a work function of 4.9 eV (a transistor where different metal materials are used for the NMOS transistor and the pMOS transistor).

In the present embodiment, although a WSiN film and a W film are used as the gate electrode material of the nMOS electrode, and the pMOS electrode material, respectively, a WSi film, a WN film may be used, respectively. Similarly, carbides such as a WSiC film, and a WC film, and borides such as a WSiB film and a WB film, may be used. In addition, when the W film is formed as the pMOS electrode material, since the W film and the polycrystalline silicon film react each other, a nitrided layer (for example, WN) should be formed between the W film and the polycrystalline silicon film as a barrier layer.

Moreover, in the present embodiment, although, combination of electrode materials primarily consisted of a W element was used, combination of electrode materials primarily consisted of a molybdenum (Mo) element in a same VIa group, or alloys thereof by the periodic law, may be used.

Further, in the present embodiment, although, combination of electrode materials primarily consisted of a W element in the VIa group was used, combination of electrode materials primarily consisted of titanium (Ti), zirconium (Zr) and hafnium (Hf) in a IVa group, or vanadium (V), niobium (Nb) and tantalum (Ta) in a Va group, may be used.

Moreover, in the present embodiment, although, a hafnium-based oxide film was used as a material of the gate insulating film, other than the hafnium-based oxide film, oxides of such as zirconium (Zr), titanium (Ti), tantalum (Ta), aluminum (Al), strontium (Sr), yttrium (Y), and lanthanum (La), or oxides of these elements and silicon such as ZrSixOy, may also be used. Furthermore, stacked films of these oxides, may also be used.

According to the second embodiment, when a tungsten electrode is formed on the gate insulating film as the pMOS electrode material, the carbon components are prevented from diffusing into the gate insulating film from inside the tungsten film, enabling the cause of fixed charges to be reduced.

### Third Embodiment

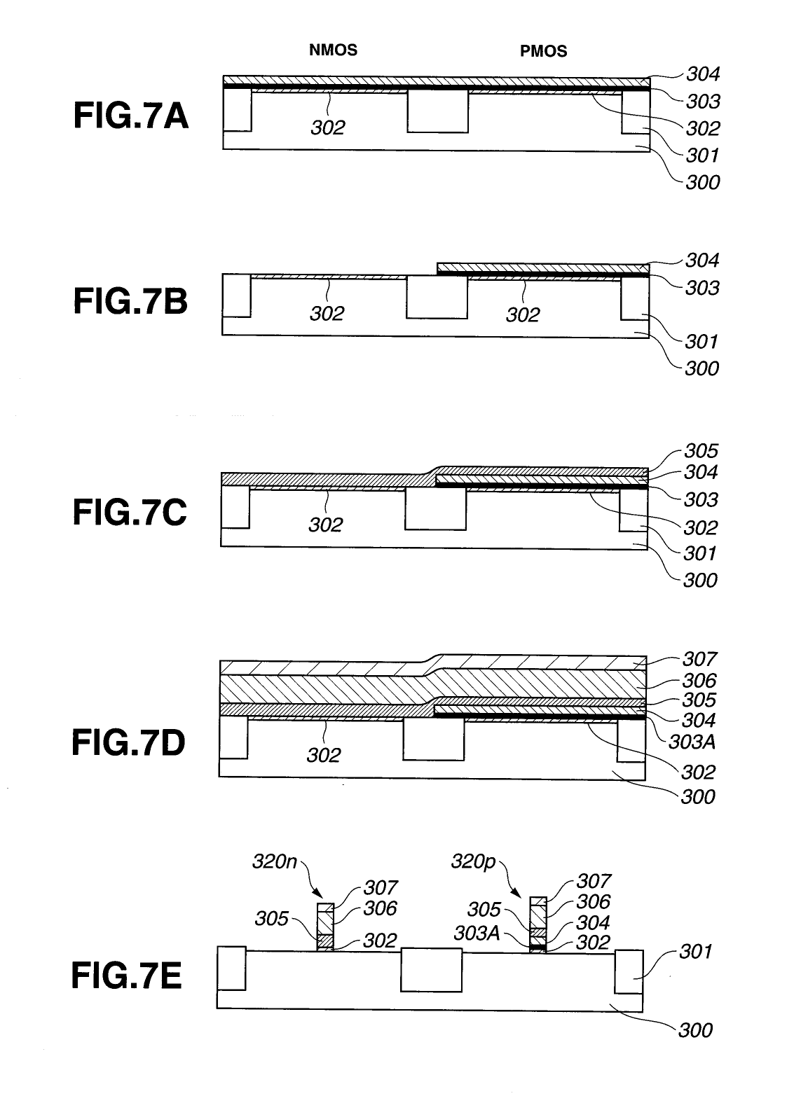

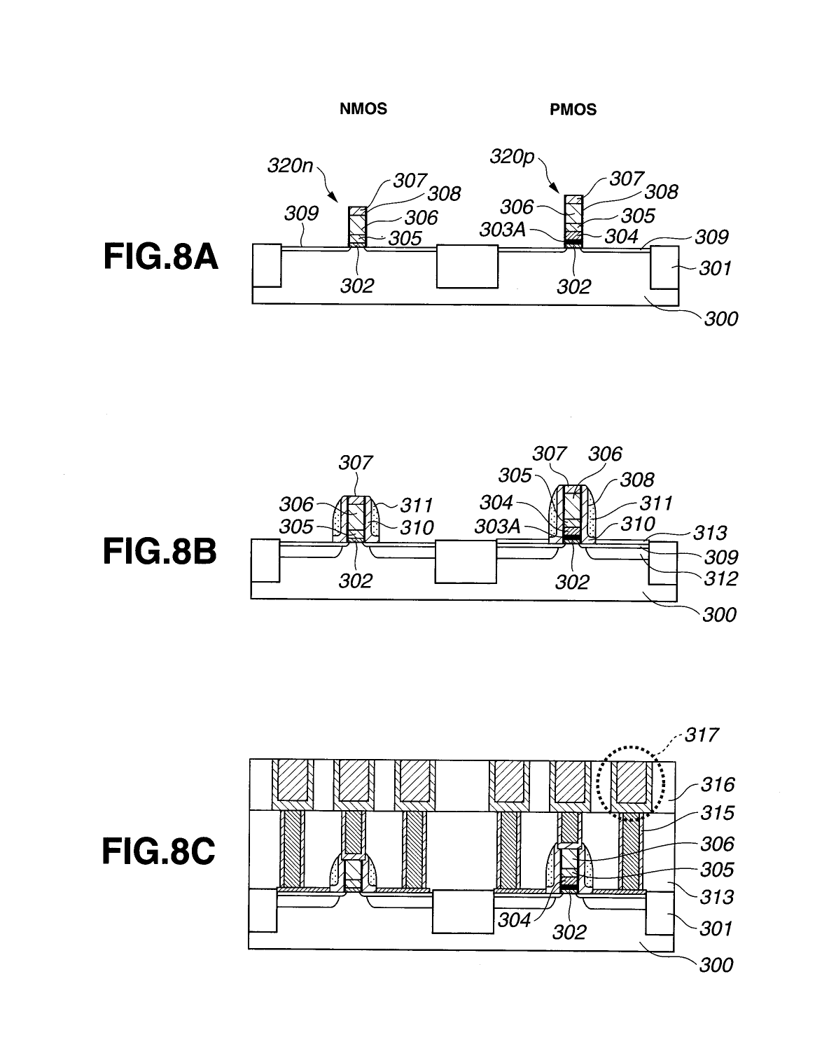

In FIGS. 7A, 7B, 7C, 7D, 7E, 8A, 8B and 8C, cross-sectional views of a part of each process of the method configured to manufacture a semiconductor device according to a third embodiment of the present invention, are illustrated, and in FIGS. 8A, 8B and 8C, cross-sectional views of a part of each process following to the process in FIG. 7E are illustrated. Here the manufacturing process configured to form an MOSFET as an MIS-transistor, will be described.

As illustrated in FIG. 7A, a gate insulating film 302 containing hafnium is formed on a single-crystal-silicon substrate 300 acting as a semiconductor substrate having element isolation 301, by means of, for example, a chemical vapor deposition (CVD) method using an organic source.

Next, a thin silicon layer 303 as thin as 0.5 nm is formed at conditions, for example, SiH₄ gas: 300 sccm, pressure: 5 Torr, and time: 10 seconds. A MoN film 304 having a work function of 5.0 eV and a thickness of 10 nm, is formed on the thin silicon layer 303, by means of, for example, a CVD method using an organic source. In addition, a MoSiC film 303A being a metal-silicon-carbon compound is formed, by the fact that the Si layer 303 is bound to C in the MoN film 304 and is further bound to Mo.

Next, as illustrated in FIG. 7B, the MoN film 304 and the silicon layer 303 in the nMOS region are released.

Further, as illustrated in FIG. 7C, for example, a MoSiN film 305 having a work function of 4.2 eV and a thickness of 10 mm, is formed by means of a CVD method.

As illustrated in FIG. 7D, a W film 306 was deposited on the MoSiN film 305 as a low resistance layer. Further, a silicon nitride film 307 was deposited on the W film 306.

As illustrated in FIG. 7E, gate electrodes 320n and 320p are formed by subjecting the silicon nitride film 307, the W film 306, the MoSiN film 305, and the MoN film 304 to anisotropic etching into a pattern having a gate width of, for example, 30 nm.

After that, as illustrated in FIG. 8A, after being deposited on the side wall parts of the electrode pattern, a silicon nitride film 308 is subjected to etching back, causing the side wall parts of the electrode pattern to have a structure surrounded by the silicon nitride film 308. Further, a shallow diffusion layers 309 are formed, for example, by ion-implanting an As⁺ ion into the NMOS region and a B⁺ ion into the pMOS region, and subjecting the both regions to a heating treatment at 800° C. for 5 seconds.

As illustrated in FIG. 8B, after being deposited on the side wall parts of the electrode pattern, silicon dioxide films 310 and silicon nitride films 311 are subjected to etching back, causing the side wall parts of the electrode pattern to have a structure surrounded by the silicon dioxide films 310 and the silicon nitride films 311. Further, a deep diffusion layers 312 are formed, for example, by ion-implanting a P+ion into the nMOS region and a B⁺ ion into the pMOS region, and subjecting the both regions to a heating treatment at 1030° C. for 5 seconds. In addition, in the third embodiment, since the shallow diffusion layers 309 are formed in first, and the deep diffusion layers are formed later, the side wall parts are not formed twice, as in FIGS. 6A and 6B in the second embodiment, instead, the side wall parts are formed only once by using the silicon dioxide films 310 and the silicon nitride films 311 which are required when the later deep diffusion layers 312 are formed.

Then, after causing reaction of Ni and the silicon substrate to occur by depositing a Ni film (10 nm) on the entire surface of the silicon substrate, and subjecting them to a heating treatment at an order of 350° C. for 30 seconds, unreacted Ni films are removed by using, for example, a mixed-solution of sulfuric acid and oxygenated water. Then, the side walls are subjected to a heating treatment at an order of 500° C. for 30 seconds. At that time, silicide layers 313 are formed on the diffusion layers.

As illustrated in FIG. 8C, a desired contact pattern is formed on a first interlayer film 314, for example, a Ti/TiN/W film is buried inside the contact pattern, and the surface of the buried contact pattern is flattened by means of a CMP method, resulting in formation of contacts 315. Subsequently, a second interlayer film 316 is deposited on the contacts 315, and a desired trench pattern is formed, subsequently a TaN/Cu film is buried inside the trench pattern, and the surface of the buried trench pattern is flattened by means of the CMP method, resulting in formation of a Cu wiring 317 electrically connecting between contacts 315.

The above-mentioned manufacturing process enables a dual metal transistor which includes an NMOS electrode having a work function of 4.2 eV composed of MoSiN and a pMOS electrode having a work function of 5.0 eV composed of a stacked layer of MoN and MoSiN to be formed.

In addition, in the present embodiment, similar to the second embodiment, as a material of the gate insulating film, other than the hafnium-based oxide film, oxides of such as zirconium (Zr), titanium (Ti), tantalum (Ta), aluminum (Al), strontium (Sr), yttrium (Y), and lanthanum (La), or oxides of these elements and silicon such as ZrSixOy, may also be used. Furthermore, stacked films of these oxides, may also be used.

According to the third embodiment, when a molybdenum nitride electrode is formed on the gate insulating film as the pMOS electrode material, the carbon components are prevented from diffusing from inside the molybdenum nitride film into the gate insulating film, enabling the cause of fixed charges to be reduced.

According to the above-mentioned embodiments, a semiconductor device where when a metal electrode is formed on a gate insulating film as a pMOS electrode material, the carbon components are prevented from diffusing from inside the metal film into the gate insulating film, enabling the cause of fixed charges to be reduced, and the manufacturing method thereof, can be provided.

Having described the embodiments of the invention referring to the accompanying drawings, it should be understood that the present invention is not limited to those precise embodiments and various changes and modifications thereof could be made by one skilled in the art without departing from the spirit or scope of the invention as defined in the appended claims.

What is claimed is:

1. A method of manufacturing a semiconductor device, comprising:
forming a gate insulating film on a semiconductor substrate;
forming a thin silicon layer on the gate insulating film; and
forming a metal film on the silicon layer, having a work function at an interface with respect to the gate insulating film of a value within a predetermined range.

2. The method of manufacturing a semiconductor device according to claim 1, wherein
the work function has a value of 4.8 eV to 5.0 eV.

3. The method of manufacturing a semiconductor device according to claim 1, wherein
the silicon layer has a thickness within a range of 0.3 nm to 2 nm.

4. The method of manufacturing a semiconductor device according to claim 2, wherein
the silicon layer has a thickness within a range of 0.3 nm to 2 nm.

5. The method of manufacturing a semiconductor device according to claim 1, wherein
the metal film is W, Mo, or compounds thereof.

6. The method of manufacturing a semiconductor device according to claim 3, wherein
the metal film is W, Mo, or compounds thereof.

7. The method of manufacturing a semiconductor device according to claim 1, wherein
the metal film is formed by a formation method using an organic material.

8. The method of manufacturing a semiconductor device according to claim 2, wherein
the metal film is formed by a formation method using an organic material.

9. The method of manufacturing a semiconductor device according to claim 3, wherein
the metal film is formed by a formation method using an organic material.

10. The method of manufacturing a semiconductor device according to claim 4, wherein
the metal film is formed by a formation method using an organic material.

11. A method of manufacturing a semiconductor device in which a pMOS transistor is formed, comprising:
forming a gate insulating film of the pMOS transistor on a semiconductor substrate;
forming a thin silicon layer on the gate insulating film; and
forming a metal film on the silicon layer, having a work function at an interface with respect to the gate insulating film of a value within a predetermined range.

12. The method of manufacturing a semiconductor device according to claim 11, wherein
the work function has a value of 4.8 eV to 5.0 eV.

13. The method of manufacturing a semiconductor device according to claim 11, wherein
the silicon layer has a thickness within a range of 0.3 nm to 2 nm.

14. The method of manufacturing a semiconductor device according to claim 11, wherein
the metal film is formed by a formation method using an organic material.

15. A semiconductor device, comprising:
a semiconductor substrate;
a gate insulating film disposed on the semiconductor substrate;
a metal film disposed on the gate insulating film, so as to have a work function at an interface with respect to the gate insulating film of a value within a predetermined range; and
a metal-silicon-carbon compound disposed between the gate insulating film and the metal film, which binds to carbon components contained in the metal film and has a predetermined thickness preventing carbon components from being precipitated into the gate insulating film from the metal film.

16. The semiconductor device according to claim 15, wherein
the work function has a value of 4.8 eV to 5.0 eV.

17. The semiconductor device according to claim 15, wherein
the metal film is W, Mo, or compounds thereof.
